(19) United States
(12) Patent Application Publication
(10) Pub. No.: US 2020/0075384 A1
(43) Pub. Date: Mar. 5, 2020

(54) Carrier Bond and Debond Using Self-Depolymerizing Polymer

(71) Applicant: Micron Technology, Inc., Boise, ID (US)

(72) Inventors: Shijian Luo, Boise, ID (US); Owen R. Fay, Meridian, ID (US)

(21) Appl. No.: 16/119,414

(22) Filed: Aug. 31, 2018

(51) Int. Cl. H01L 21/683

(52) U.S. Cl. CPC H01L 21/6835; H01L 2221/68327; H01L 2221/68381

(57) ABSTRACT

A semiconductor device assembly that includes a semiconductor device having a first side and a second side connected to a substrate. A layer of self-depolymerizing polymer connects the semiconductor device to the substrate. The layer of self-depolymerizing layer is positioned between the first side of the semiconductor device and the substrate. The layer of self-depolymerizing polymer is configured to selectively release the substrate from the semiconductor device. The layer of self-depolymerizing polymer selectively depolymerizes to release the substrate. The substrate enables processing to occur on the second side of the semiconductor device. A material may be applied to a portion of the layer of self-depolymerizing polymer causing the entire layer to depolymerize and release the substrate from the semiconductor device. Energy may be applied to a portion of the layer of self-depolymerizing polymer causing the entire layer to depolymerize and release the substrate from the semiconductor device.

### FIELD

The embodiments described herein relate to semiconductor device assemblies and methods of making a semiconductor device assembly that includes a self-depolymerizing polymer that bonds a substrate to a semiconductor device and enables the selective removal of the substrate from the semiconductor device.

### BACKGROUND

A substrate, such as a carrier substrate, is often used to support a semiconductor device, such as a semiconductor wafer that includes a plurality of dies, to permit further processing on the semiconductor device. For example, a semiconductor device may include a plurality of structures, such as pads, pillars, vias, or the like, on a first or front side of the device. During the processing of the semiconductor device, the thickness of the semiconductor device may need to be reduced. Various processes, such as, but not limited to, chemical-mechanical planarization, grinding, and/or dry etching, may be applied to the back, or second, side of the semiconductor device to remove material from the semiconductor device. For example, the thickness of the semiconductor device may be reduced from a first thickness, such as 775 microns, down to a second thickness, such as 30 to 70 microns, using various processes known by one of ordinary skill in the art. Furthermore, various processes, such as, metallization, photolithography patterning, wet or dry etching, and electrical chemical plating, may be applied to the back, or second, side of the semiconductor device to form structures such as pads, pillars, or the like, for the semiconductor device.

Presently, a semiconductor device, such as a semiconductor wafer, may be temporarily bonded to a substrate, such as a carrier wafer, with a temporary adhesive to form a temporary semiconductor device assembly. For example, the first or front side of the semiconductor wafer may be bonded to a carrier wafer with a temporary adhesive that is spin coated onto the carrier wafer. After completing the processing on the second, or back, side of the semiconductor wafer, the semiconductor wafer is removed from the carrier wafer. Typically, the semiconductor wafer is removed, or debonded, from the carrier wafer by thermal/mechanical sliding. In other words, the temporary semiconductor device assembly is heated and force is applied to slide the semiconductor wafer off the carrier wafer. The present process of removing the semiconductor wafer from the carrier wafer may result in, among other things, die cracking and/or pillar smearing. Further, the present process may result in breakage of the semiconductor wafer itself. The edges of the semiconductor wafer may break, crack, or chip during the removal/debonding process.

A temporary adhesive having a relatively low glass transition temperature may be used to bond the carrier to the semiconductor device. The adhesive with the relatively low glass transition temperature is used to better enable that the carrier may be removed from the semiconductor device after the requisite processing. However, the semiconductor carrier and substrate assembly may be subjected to elevated temperatures during the processing potentially causing undesired movement between the carrier and semiconductor device.

A glass carrier may be used to support a semiconductor device during processing. After the requisite processing on the backside of the semiconductor device, a laser may be applied to the adhesive through the glass carrier to release the glass carrier from the semiconductor device. However, glass carriers typically have poor thermal transfer and high mismatch of coefficient of thermal expansion (CTE) which cause wafer warpage issues, and may also sag during processing of the semiconductor device due to the low elastic modulus.

A silicon (Si) carrier substrate having a high thermal conductivity, good rigidity, and a CTE match to a Si semiconductor device may have various advantages compared to a glass carrier used for semiconductor device backside processing. However, a Si carrier typically cannot be removed from the semiconductor device by applying a laser to the adhesive. Instead, a Si carrier may be removed by a thermal/mechanical process, which potentially may damage the semiconductor device, as discussed herein.

Additional drawbacks and disadvantages may exist.

### BRIEF DESCRIPTION OF THE DRAWINGS

FIG. 1 is a schematic of an embodiment of a semiconductor device assembly.

FIG. 2 is a schematic of an embodiment of a semiconductor device assembly with a second surface of a semiconductor device that has been processed.

FIG. 3 is a schematic of an embodiment of a semiconductor device assembly being supported on a film frame.

FIG. 4 is a schematic of a material applied to a self-depolymerizing polymer layer of an embodiment of a semiconductor device assembly.

FIG. 5 is a schematic of an embodiment of a semiconductor device separated from a substrate.

FIG. 6 is a flow chart of an embodiment of a method of making a semiconductor device assembly.

FIG. 7 is a schematic of a portion of a polymer chain that may comprise an embodiment of a layer of self-depolymerizing polymer.

FIG. 8 is a schematic of the end-capping group being removed from polymer chain of FIG. 7.

FIG. 9 is a schematic of the polymer chain of FIG. 7 self-depolymerizing upon removal of the end-capping group.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure as defined by the appended claims.

### DETAILED DESCRIPTION

In this disclosure, numerous specific details are discussed to provide a thorough and enabling description for embodiments of the present disclosure. One of ordinary skill in the art will recognize that the disclosure can be practiced without one or more of the specific details. Well-known structures and/or operations often associated with semiconductor devices and semiconductor device packages may not be shown and/or may not be described in detail to avoid obscuring other aspects of the disclosure. In general, it should be understood that various other devices, systems, and/or methods in addition to those specific embodiments disclosed herein may be within the scope of the present disclosure.

The terms “semiconductor device assembly” can refer to an assembly of one or more semiconductor devices, semiconductor device packages, and/or substrates, which may include interposers, supports, and/or other suitable substrates. The semiconductor device assembly may be manufactured as, but not limited to, discrete package form, strip or matrix form, and/or wafer panel form. The term “semiconductor device” generally refers to a solid-state device that includes semiconductor material. A semiconductor device can include, for example, a semiconductor substrate, wafer, panel, or a single die from a wafer or substrate. A semiconductor device may refer herein to a semiconductor die, but semiconductor devices are not limited to semiconductor dies.

As used herein, the terms “vertical,” “lateral,” “upper,” and “lower” can refer to relative directions or positions of features in the semiconductor devices and/or semiconductor device assemblies shown in the Figures. For example, “upper” or “uppermost” can refer to a feature positioned closer to the top of a page than another feature. These terms, however, should be construed broadly to include semiconductor devices and/or semiconductor device assemblies having other orientations, such as inverted or inclined orientations where top/bottom, over/under, above/below, up/down, and left/right can be interchanged depending on the orientation.

Various embodiments of this disclosure are directed to semiconductor devices, semiconductor device assemblies, semiconductor packages, semiconductor device packages, and methods of making and/or operating semiconductor devices.

An embodiment of the disclosure is a semiconductor device assembly comprising a semiconductor device having a first side and a second side and a substrate. A layer of self-depolymerizing polymer is configured to connect the semiconductor device to the substrate. The layer of self-depolymerizing layer is positioned between the first side of the semiconductor device and the substrate. The layer of self-depolymerizing polymer is configured to selectively release the substrate from the semiconductor device. The layer of self-depolymerizing polymer selectively depolymerizes to release the substrate.

An embodiment of the disclosure is a semiconductor device assembly comprising a semiconductor device having a first surface and a second surface opposite the first surface with the first surface of the semiconductor device being an active surface. The semiconductor device includes a substrate and a layer of self-depolymerizing polymer that connects the first surface semiconductor device to the substrate. The layer of self-depolymerizing polymer is configured to selectively self-depolymerize to release the substrate from the first surface of the semiconductor device.

An embodiment of the disclosure is a method of making a semiconductor device assembly. The method comprises providing a substrate and providing a semiconductor device having a first surface and a second surface opposite of the first surface. The method comprises attaching the substrate to the first surface of the semiconductor device with a layer of self-depolymerizing polymer.

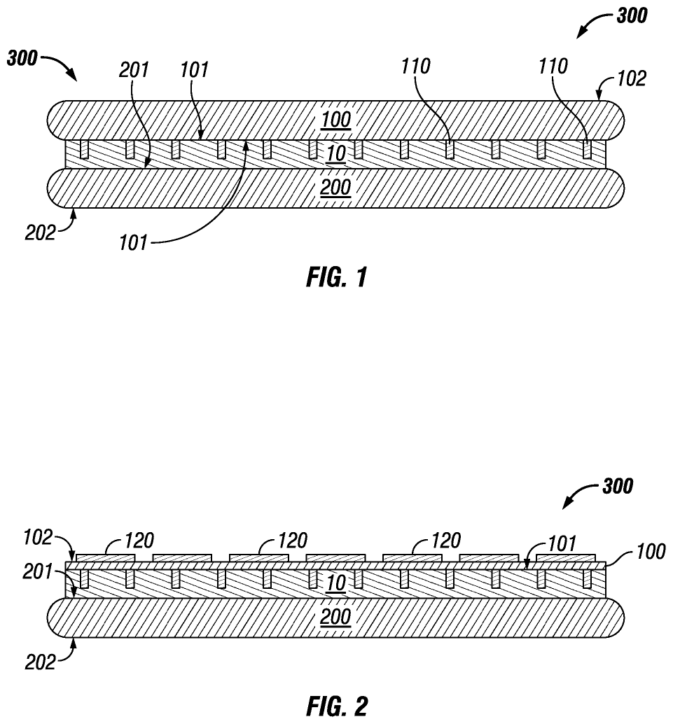

FIG. 1 is a schematic of an embodiment of a semiconductor device assembly 300. The semiconductor device assembly 300 includes a semiconductor device 100 and a substrate 200. The substrate 200 includes a first, or top, surface, or side, 201 and a second, or bottom, surface, or side, 202 opposite of the first surface 201. The substrate 200 is a carrier that enables processing on the bottom or backside of the semiconductor device 100, as discussed herein. The substrate 200 may be comprised of various materials as would be appreciated by one of ordinary skill in the art having the benefit of this disclosure. For example, the substrate 200 may be, but is not limited to, silicon, ceramic, glass, metal, plastic, a composite material, a laminate material, or the like. The size, shape, location, and/or configuration of the carrier substrate 200 is shown for illustrative purposes and may be varied depending on the application as would be appreciated by one of ordinary skill in the art having the benefit of this disclosure.

The semiconductor device 100 includes a first, or top, surface, or side, 101 and a second, or bottom, surface, or side, 102 opposite the first surface 101. The semiconductor device 100 includes a plurality of structures 110 on the first surface 101. The first surface 101 of the semiconductor device 100 is an active surface of the semiconductor device 100. The structures 110 are schematically represented in FIG. 1 and may comprise various structures, such as for example pads, pillars, or the like, as would be appreciated by one of ordinary skill in the art. A layer of self-depolymerizing polymer 10 has been deposited onto the first surface 101 of the semiconductor device 100 in order to selectively attach the semiconductor device 100 to the carrier substrate 200 to form a semiconductor device assembly 300, shown in FIG. 1. Alternatively, the layer of self-depolymerizing polymer 10 may be deposited onto the first, or top, surface 201 of the substrate 200 as would be appreciated by one of ordinary skill in the art having the benefit of this disclosure.

The semiconductor device 100 may be a semiconductor wafer and the substrate 200 may be a carrier wafer as would be appreciated by one of ordinary skill in the art. The size, shape, location, number, and/or configuration of the layer of self-depolymerizing polymer 10, structures 110, and the semiconductor device 100 are shown for illustrative purposes and may be varied depending on the application as would be appreciated by one of ordinary skill in the art having the benefit of this disclosure.

The layer of self-depolymerizing polymer 10 between the first side 101 of the semiconductor device 100 and the first side 201 of the substrate 200 enables the semiconductor device 100 to be selectively attached to the substrate 200 to form a semiconductor device assembly 300, shown in FIG. 1. A self-depolymerizing polymer is a polymer that self-depolymerizes once the end-capping group of the polymer is released. If the entire layer of self-depolymerizing polymer 10 is comprised of one polymer chain, then the entire layer of self-depolymerizing polymer 10 will depolymerize upon removal of the end-capping group. If the layer of self-depolymerizing polymer 10 is comprised of multiple polymer chains, then the end-capping groups of each of the polymer chains will need to be released from the layer of self-depolymerizing polymer 10 to depolymerize.

Various mechanism may be used to release the end-capping group of the polymer if the layer is comprised one polymer chain or to release the end-capping groups of each polymer of the layer of self-depolymerizing polymer 10 if the layer is comprised of multiple polymer chains as would be appreciated by one of ordinary skill in the art having the benefit of this disclosure. For example, a material may be applied to the layer of self-depolymerizing polymer 10 that causes the end-capping group to be released. For example, a material such as, but not limited to, hydrogen peroxide or fluoride may be applied to the layer of self-depolymerizing polymer 10 causing the end-capping group to be released, which results in the depolymerizing of the entire layer 10. Alternatively, the application of energy to at least a portion of the layer of self-depolymerizing polymer 10 may cause the end-capping group to be released. For example, ultraviolet light or heat applied to a portion of the layer of self-depolymerizing polymer 10 may cause the end-capping group to be released.

The depolymerization of the layer of self-depolymerizing polymer 10 causes the substrate 200 to be released from the semiconductor device 100. The polymer chain of the layer of self-depolymerizing polymer 10 may self-depolymerize into a monomer depending on the polymer chain. Various self-depolymerizing polymers may be used to form the layer of self-depolymerizing polymer 10 as would be appreciated by one of ordinary skill in the art having the benefit of this disclosure. The layer of self-depolymerizing polymer 10 may be comprised of, but is not limited to, polyether, polyurethane, polycarbonate, polyimide, and/or a combination thereof.

The semiconductor device assembly 300 enables processing on the second side 102 of the semiconductor device 100. The processing on the second side 102 of the semiconductor device 100 may include removing material from the semiconductor device 100 and/or forming structures 120 on the second side 102 of the semiconductor device 100, as shown in FIG. 2.

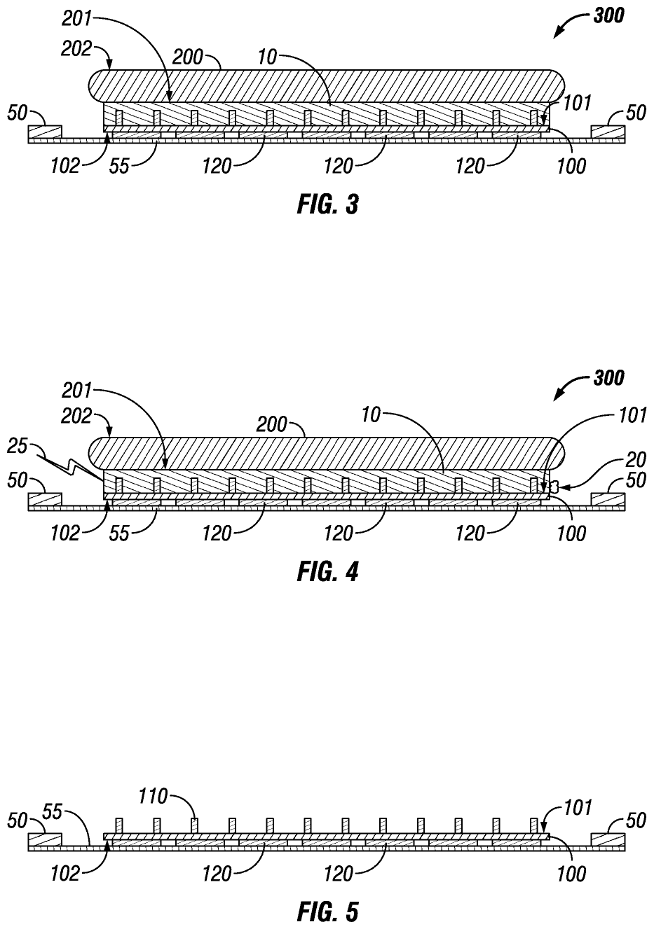

After completing the processing on the second side 102 of the semiconductor device 100 of the semiconductor device assembly 300, the semiconductor device assembly 300 may be positioned on mounting tape or film 55 connected to a film frame 50 with the second side 102 of the semiconductor device 100 resting on the mounting tape 55 as shown in FIG. 3. The film frame 50 and mounting tape 55 may be used to support the semiconductor device assembly 300 during the removal of the substrate 200, as discussed herein.

As discussed herein, a material 20 may be applied to the layer of self-depolymerizing polymer 10 of the semiconductor device assembly 300, as shown in FIG. 4. The material 20 may need to be applied to only an edge of the layer of self-depolymerizing polymer 10 to release the end-capping group of the polymer and start the self-depolymerizing process of the layer of self-depolymerizing polymer 10. The application of the material 20 to the layer of self-depolymerizing polymer 10 causes a chain reaction within the layer of self-depolymerizing polymer 10 the depolymerizes the entire layer of self-depolymerizing polymer 10. The depolymerization of the layer of self-depolymerizing polymer 10 releases the substrate 200 from the semiconductor device 100 as shown in FIG. 5. Various materials 20 may be used to cause the self-depolymerization of the layer of self-depolymerizing polymer 10 as would be appreciated by one of ordinary skill in the art having the benefit of this disclosure. For example, the material may be, but is not limited to, hydrogen peroxide or fluoride. Alternatively, ultraviolet light may be applied to the layer of self-depolymerizing polymer 10 causing the end-capping group to be released, which results in the depolymerizing of the entire layer 10 as discussed herein.

As discussed herein, energy 25 may be applied to the layer of self-depolymerizing polymer 10 of the semiconductor device assembly 300 to cause the layer of self-depolymerizing polymer 10 to self-depolymerize releasing the substrate 200 from the semiconductor device 100. FIG. 4 shows energy 25, schematically depicted as a lightning bolt, being applied to the layer of self-depolymerizing polymer 10. FIG. 4 shows the both material 20 and energy 25 for clarity purposes and either one of material 20 and energy 25 may be applied to the layer of self-depolymerizing polymer 10 causing the end-capping group of the polymer(s) to be released resulting in the depolymerization of the layer of self-depolymerizing polymer 10 as would be appreciated by one of ordinary skill in the art having the benefit of this disclosure. Various forms of energy 25 may be applied to the layer of self-depolymerizing polymer 10 causing the end-capping group of the polymer(s) to be released depending on the application as would be appreciated by one of ordinary skill in the art having the benefit of this disclosure. For example, the energy 25 may be, but is not limited to, an application of ultraviolet laser or a predetermined temperature.

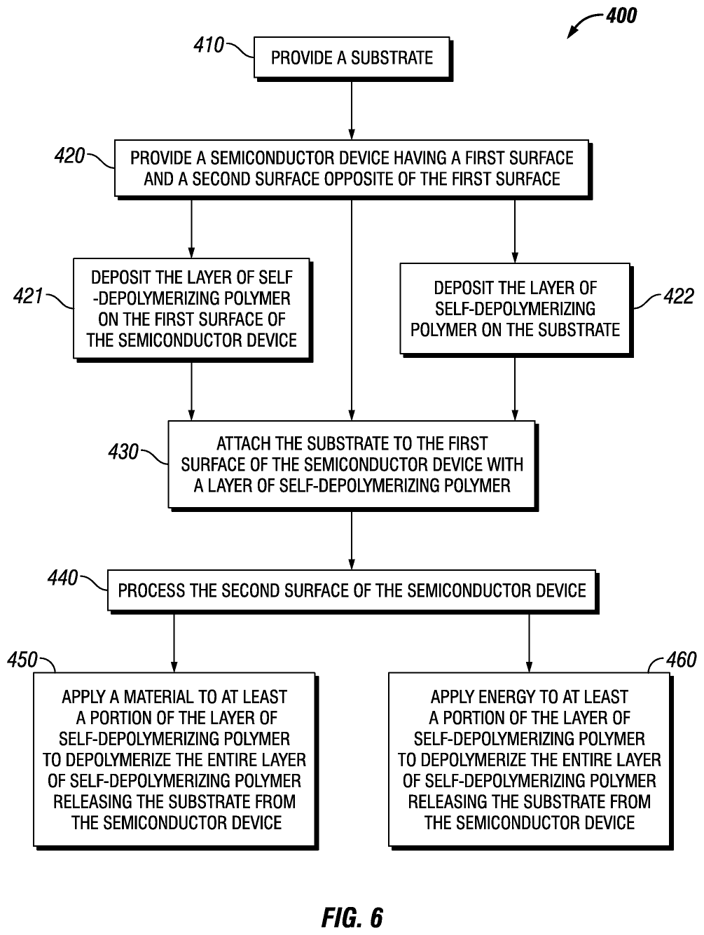

FIG. 6 is a flow chart for a method 400 of making a semiconductor device assembly. The method 400 includes providing a substrate, at 410, and providing a semiconductor device having a first surface and a second surface opposite of the first surface, at 420. The method 400 comprises attaching the substrate to the first surface of the semiconductor device with a layer of self-depolymerizing polymer, at 430. The layer of self-depolymerizing polymer may be deposited on the first surface of the semiconductor device, at 421, prior to attaching the substrate to the first surface of the semiconductor device. The layer of self-depolymerizing polymer may be deposited on the substrate, at 422, prior to attaching the substrate to the first surface of the semiconductor device.

The method 400 may include processing the second surface of the semiconductor device, at 440. The processing on the second surface of the semiconductor device may vary depending on the application as would be appreciated by one of ordinary skill in the art having the benefit of this disclosure. For example, material may be removed from the second surface of the semiconductor device and/or vias may be formed in the second surface of the semiconductor device. The method 400 may comprise applying a material to at least a portion of the layer of self-depolymerizing polymer to depolymerize the entire layer of self-depolymerizing polymer releasing the substrate from the semiconductor device, at 450. The method 400 may comprise applying energy to at least a portion of the layer of self-depolymerizing polymer to depolymerize the entire layer of self-depolymerizing polymer releasing the substrate from the semiconductor device, at 460.

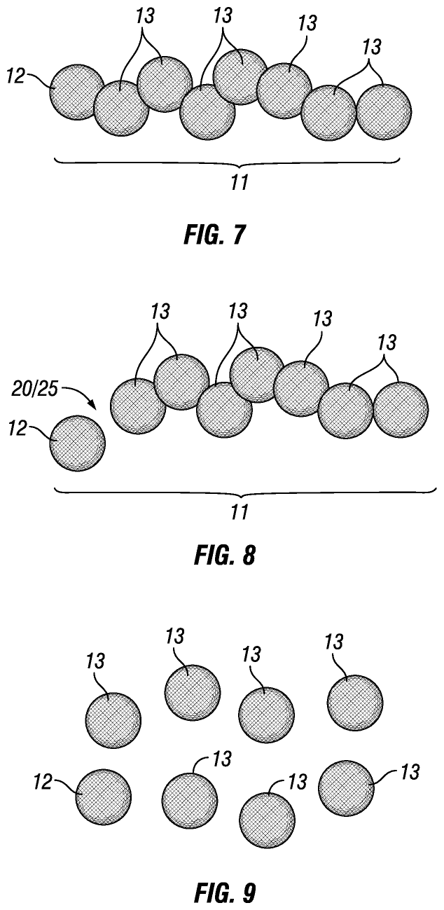

FIG. 7 is a schematic of a portion of a polymer chain 11 that may comprise an embodiment of a layer of self-depolymerizing polymer 10 (shown in FIGS. 1-4). The polymer chain 11 comprises an end-capping group 12 connected onto the end of polymer molecules 13 to form a polymer chain 11. As discussed herein, the layer of self-depolymerizing polymer 10 may comprise multiple different polymer chains 11 each comprised of an end-capping group 12 connected onto the end of polymer molecules 13. FIG. 7 is a schematic showing a single polymer chain 11 for clarity. The length, shape, configuration, number, and/or location of the end-capping group 12 and polymer molecules 13 are shown for illustrative purpose and may be varied depending on the application as would be appreciated by one of ordinary skill in the art having the benefit of this disclosure. For example, the polymer chain 11 may include more or less polymer molecules and/or each end of the polymer chain 11 may include an end-capping group 12.

FIG. 8 is a schematic showing that the end-capping group 12 has been released from the polymer chain 11 of polymer molecules 13. As discussed herein a material 20 and/or energy 25 (shown schematically by an arrow) may have been applied to the end-capping group 12 causing the end-capping group 12 to be released from the polymer chain 11. Once the end-capping group 12 is released from the polymer chain 11, the rest of the polymer chain 11 self-depolymerizes as schematically shown in FIG. 9. The self-depolymerization of the polymer chain 11 causes the chain 11 to break apart. As discussed herein, the self-depolymerization of the layer of self-depolymerizing polymer 10 may be used to release a substrate from a semiconductor device.

Although this disclosure has been described in terms of certain embodiments, other embodiments that are apparent to those of ordinary skill in the art, including embodiments that do not provide all of the features and advantages set forth herein, are also within the scope of this disclosure. The disclosure may encompass other embodiments not expressly shown or described herein. Accordingly, the scope of the present disclosure is defined only by reference to the appended claims and equivalents thereof.

What is claimed is:

1. A semiconductor device assembly comprising:
a semiconductor device having a first side and a second side;
a substrate; and
a layer of self-depolymerizing polymer configured to connect the semiconductor device to the substrate, the layer of self-depolymerizing polymer positioned between the first side of the semiconductor device and the substrate, wherein the layer of self-depolymerizing polymer is configured to selectively self-depolymerize and release the substrate from the semiconductor device.

2. The semiconductor device assembly of claim 1, wherein the layer of self-depolymerizing polymer is configured to self-depolymerize upon the application of a material to a portion of the layer of self-depolymerizing polymer.

3. The semiconductor device assembly of claim 2, wherein the material is hydrogen peroxide or fluoride.

4. The semiconductor device assembly of claim 1, wherein the layer of self-depolymerizing polymer is configured to self-depolymerize upon the application of energy to a portion of the layer of self-depolymerizing polymer.

5. The semiconductor device assembly of claim 4, wherein the energy is heat or ultraviolet light.

6. The semiconductor device assembly of claim 1, wherein the layer of self-depolymerizing polymer is polyether, polyurethane, polycarbonate, polyimide, or a combination thereof.

7. The semiconductor device assembly of claim 1, wherein the layer of self-depolymerizing polymer is comprised of one polymer chain.

8. The semiconductor device assembly of claim 7, wherein the layer of self-depolymerizing polymer self-depolymerizes upon removal of an end-capping group of the self-depolymerizing polymer.

9. The semiconductor device assembly of claim 1, wherein the layer of self-depolymerizing polymer is comprised of multiple polymer chains.

10. The assembly of claim 9, the layer of self-depolymerizing polymer self-depolymerizes upon removal of an end-capping group of the each of the polymers comprising the self-depolymerizing polymer.

11. A semiconductor device assembly comprising:
a semiconductor device having a first surface and a second surface opposite the first surface, the first side of the semiconductor device being an active surface;
a substrate; and
a layer of self-depolymerizing polymer that connects the first surface of the semiconductor device to the substrate, wherein the layer of self-depolymerizing polymer is configured to selectively self-depolymerize to release the substrate from the first surface of the semiconductor device.

12. The semiconductor device assembly of claim 11, wherein the layer of self-depolymerizing polymer is configured to self-depolymerize and release the substrate from the first surface of the semiconductor device upon removal of an end-capping group of the layer of self-depolymerizing polymer.

13. The semiconductor device assembly of claim 12, wherein an application of hydrogen peroxide or fluoride removes the end-capping group of the layer of self-depolymerizing polymer.

14. A method of making a semiconductor device assembly comprising:
providing a substrate;
providing a semiconductor device having a first surface and a second surface opposite of the first surface; and
attaching the substrate to the first surface of the semiconductor device with a layer of self-depolymerizing polymer.

15. The method of claim 14, comprising depositing the layer of self-depolymerizing polymer on the first surface of the semiconductor device prior to attaching the substrate to the first surface of the semiconductor device.

16. The method of claim 14, comprising depositing the layer of self-depolymerizing polymer on the substrate prior to attaching the substrate to the first surface of the semiconductor device.

17. The method of claim 14, comprising processing the second surface of the semiconductor device.

18. The method of claim 17, wherein processing comprises removing material from the second surface of the semiconductor device.

19. The method of claim 18, comprising applying a material to a least a portion of the layer of self-depolymerizing polymer to depolymerize the entire layer of self-depolymerizing polymer releasing the substrate from the semiconductor device.

20. The method of claim 18, comprising applying energy to a least a portion of the layer of self-depolymerizing polymer to depolymerize the entire layer of self-depolymerizing polymer releasing the substrate from the semiconductor device.
